(19) United States
(12) Patent Application Publication
(10) Pub. No.: US 2026/0110660 A1
(43) Pub. Date: Apr. 23, 2026

(54) USE OF SILK AS AN OXIDE SUBSTITUTE IN SEMICONDUCTOR DEVICES AND SENSORS, AND METHODS OF MAKING THE SAME

(71) Applicant: Trustees of Tufts College, MEDFORD, MA (US)

(72) Inventors: Fiorenzo G. Omenetto, Lexington, MA (US); Giorgio E. Bonacchini, Schio (VI) (IT); Beom Joon Kim, Fremont, CA (US)

(21) Appl. No.: 19/368,018

(22) Filed: Oct. 24, 2025

Related U.S. Application Data
(63) Continuation of application No. PCT/US24/26802, filed on Apr. 29, 2024.
(60) Provisional application No. 63/499,130, filed on Apr. 28, 2023.

(51) Int. Cl. G01N 27/414; H10K 10/46

(52) U.S. Cl. CPC G01N 27/414; H10K 10/46

(57) ABSTRACT

A device may include a first layer, wherein the first layer is conductive or semiconductive. A device may include a regenerated amphiphilic protein layer on the first layer, the regenerated amphiphilic protein layer structured such that: in a first hydration state of the regenerated amphiphilic protein layer, a first electrical double layer (EDL) is formed at an interface between the first layer and the regenerated amphiphilic protein layer.

### CROSS-REFERENCE TO RELATED APPLICATION

This application claims benefit of and is a continuation of International Patent Application No. PCT/US2024/026802 (Attorney Docket No. 2095.0605), filed Apr. 29, 2024, and entitled “USE OF SILK AS AN OXIDE SUBSTITUTE IN SEMICONDUCTOR DEVICES AND SENSORS, AND METHODS OF MAKING THE SAME,” International Pub. No. WO 2024/228948, which is hereby incorporated by reference in its entirety for all purposes.

International Patent Application No. PCT/US2024/026802 relates to, incorporates by reference for all purposes, and claims priority to U.S. application Ser. No. 63/499,130 (Attorney Docket No. 2095.0517), filed Apr. 28, 2023.

### STATEMENT REGARDING FEDERALLY FUNDED RESEARCH

This invention was made with government support under grant #N00014-19-2399 awarded by the US Navy, Office of Naval Research. The government has certain rights in the invention.

### BACKGROUND

Semiconductor materials, devices, and processing have traditionally involved materials and processes that are not sustainable or renewable. A need exists for materials and processes for producing semiconductor devices that are sustainable and renewable.

### SUMMARY

Nanoscale silk layers on semiconductors enable building transistors that can switch between ionic or dielectric behavior allowing a new class of hybrid, functional devices where semiconductor and biopolymer technologies coexist, leveraging their respective strengths.

In some aspects, the techniques described herein relate to a device, including: a first layer, wherein the first layer is conductive or semiconductive; a regenerated amphiphilic protein layer on the first layer, the regenerated amphiphilic protein layer structured such that: in a first hydration state of the regenerated amphiphilic protein layer, a first electrical double layer (EDL) is formed at an interface between the first layer and the regenerated amphiphilic protein layer.

In some aspects, the techniques described herein relate to a device, further including: a second layer, wherein: the second layer is conductive or semiconductive; the regenerated amphiphilic protein layer is on the second layer; and in the first hydration state of the regenerated amphiphilic protein layer, a second EDL is formed at an interface between the second layer and the regenerated amphiphilic protein layer.

In some aspects, the techniques described herein relate to a device, wherein the regenerated amphiphilic protein layer is accessible to environmental moisture.

In some aspects, the techniques described herein relate to a device, wherein the first hydration state is initiated by capture of the environmental moisture by the regenerated amphiphilic protein layer.

In some aspects, the techniques described herein relate to a device, wherein the regenerated amphiphilic protein layer is formed by: depositing silk fibroin films each less than 5 nm through spin-coating a 0.01-0.1% wt or 0.05% wt silk solution to form a deposited silk film; rinsing the deposited silk film in a bath of deionized water; and patterning the deposited silk film.

In some aspects, the techniques described herein relate to a device, wherein the patterning the deposited silk film includes O₂ plasma etching the deposited silk film through a photoresist mask using poly(methyl methacrylate) (PMMA) as a passivation layer.

In some aspects, the techniques described herein relate to a device, wherein the first and second EDLs formed in the first hydration state enhance current flow by over six orders of magnitude.

In some aspects, the techniques described herein relate to a device, wherein: the first EDL includes electronic surface charges and oppositely charged ions aligned at the interface between the first layer and the regenerated amphiphilic protein layer; and the second EDL includes electronic surface charges and oppositely charged ions aligned at the interface between the second layer and the regenerated amphiphilic protein layer.

In some aspects, the techniques described herein relate to a device, wherein the first layer is a lateral gate electrode of a transistor, and the second layer is a semiconductor layer of the transistor.

In some aspects, the techniques described herein relate to a device, wherein the lateral gate electrode and the semiconductor layer do not overlap in a cross-section view.

In some aspects, the techniques described herein relate to a device, wherein the semiconductor layer is formed of a semiconducting material.

In some aspects, the techniques described herein relate to a device, wherein the semiconducting material includes indium gallium zinc oxide (IGZO).

In some aspects, the techniques described herein relate to a device, wherein in a second hydration state of the regenerated amphiphilic protein layer, the first EDL and the second EDL are not formed.

In some aspects, the techniques described herein relate to a device, wherein the second hydration state corresponds to an absence of captured H₂O molecules in the regenerated amphiphilic protein layer.

In some aspects, the techniques described herein relate to the device of 14, wherein in the second hydration state, capacitive coupling between the lateral gate electrode and the semiconductor layer is determined by a permittivity of the regenerated amphiphilic protein layer.

In some aspects, the techniques described herein relate to a device, wherein capacitive coupling is insufficient for modulating a charge carrier density within the semiconductor layer.

In some aspects, the techniques described herein relate to a device, wherein when the regenerated amphiphilic protein layer transitions from the second hydration state to the first hydration state, the transistor transitions from a field-effect operating mode to an electrolyte-gated operating mode.

In some aspects, the techniques described herein relate to a device, further including: a substrate, wherein the first layer and the second layer are each on the substrate.

In some aspects, the techniques described herein relate to a device, further including: a bottom gate electrode between the substrate and the semiconductor layer In some aspects, the techniques described herein relate to a device, wherein the substrate is Si/SiO₂.

In some aspects, the techniques described herein relate to a device, wherein the regenerated amphiphilic protein layer is a regenerated silk fibroin layer.

In some aspects, the techniques described herein relate to a device, wherein the regenerated amphiphilic protein layer has a thickness of between 1 nm and 20 nm, between 2 nm and 15 nm, or between 3 nm and 10 nm, including but not limited to, a thickness of at least 1 nm, at least 2 nm, at least 3 nm, at least 4 nm, or at least 5 nm, and a thickness of at most 20 nm, at most 15 nm, at most 10 nm, or at most 5 nm.

In some aspects, the techniques described herein relate to a semiconductor device, including: a substrate; a source electrode, a drain electrode, a lateral gate electrode, and a semiconductor layer, each on the substrate; and a regenerated amphiphilic protein layer on the semiconductor layer and the gate electrode, wherein the regenerated amphiphilic protein layer is structured to be exposed to humidity to capture H₂O molecules and thereby transition from a field-effect mode to an electrolyte-gated mode.

In some aspects, the techniques described herein relate to a semiconductor device, wherein the humidity is from breath exhalation.

In some aspects, the techniques described herein relate to a semiconductor device, wherein the regenerated amphiphilic protein layer is structured to be in the electrolyte-gated mode during the breath exhalation.

In some aspects, the techniques described herein relate to a semiconductor device, wherein in the electrolyte-gated mode: a first electric double layer (EDL) is formed at an interface between the lateral gate electrode and the regenerated amphiphilic protein layer; and a second electric double layer (EDL) is formed at an interface between the regenerated amphiphilic protein layer and the semiconductor layer.

In some aspects, the techniques described herein relate to a semiconductor device, wherein the regenerated amphiphilic protein layer is further structured for the captured H₂O molecules to be extracted during breath inhalation to thereby transition from the electrolyte-gated mode to the field-effect mode.

In some aspects, the techniques described herein relate to a semiconductor device, wherein the regenerated amphiphilic protein layer is structured to be in the electrolyte-gated mode during the breath exhalation and in the field-effect mode during the breath inhalation.

In some aspects, the techniques described herein relate to a semiconductor device, wherein: the breath exhalation causes the regenerated amphiphilic protein layer to transition from the field-effect mode to the electrolyte-gated mode in about 30 milliseconds; and the breath inhalation causes the regenerated amphiphilic protein layer to transition from the electrolyte-gated mode to the field-effect mode in about 300 milliseconds.

In some aspects, the techniques described herein relate to a semiconductor device, wherein the transitions between the electrolyte-gated mode and the field-effect mode enable tracking of multiple breath cycles.

In some aspects, the techniques described herein relate to a semiconductor device, further including: a bottom gate electrode between the substrate and the semiconductor layer.

In some aspects, the techniques described herein relate to a semiconductor device, wherein the regenerated amphiphilic protein layer is a regenerated silk fibroin layer.

In some aspects, the techniques described herein relate to a device, wherein the regenerated amphiphilic protein layer has a thickness of between 1 nm and 20 nm, between 2 nm and 15 nm, or between 3 nm and 10 nm, including but not limited to, a thickness of at least 1 nm, at least 2 nm, at least 3 nm, at least 4 nm, or at least 5 nm, and a thickness of at most 20 nm, at most 15 nm, at most 10 nm, or at most 5 nm.

In some aspects, the techniques described herein relate to a method of forming a regenerated amphiphilic protein layer, including: depositing silk fibroin films each less than 5 nm through spin-coating a 0.01-0.1% wt or 0.05% wt silk solution to form a deposited silk film; rinsing the deposited silk film in a bath of deionized water; and patterning the deposited silk film.

In some aspects, the techniques described herein relate to a method, wherein the patterning the deposited silk film includes O₂ plasma etching the deposited silk film through a photoresist mask using poly(methyl methacrylate) (PMMA) as a passivation layer.

In some aspects, the techniques described herein relate to a method, wherein the generated amphiphilic protein layer is formed on a first layer and a second layer, wherein the first layer is conductive or semiconductive and the second layer is conductive or semiconductive.

In some aspects, the techniques described herein relate to a method, wherein the regenerated amphiphilic protein layer is structured such that in a hydrated state, a first electrical double layer (EDL) is formed at an interface between the first layer and the regenerated amphiphilic protein layer and a second EDL is formed at an interface between the second layer and the regenerated amphiphilic protein layer.

### BRIEF DESCRIPTION OF THE FIGURES

The disclosure and the following detailed description of certain aspects thereof may be understood by reference to the following figures:

FIG. 1 depicts a device including a regenerated amphiphilic protein layer according to an example embodiment of the disclosure.

FIG. 2 depicts a flowchart illustrating a method for forming a regenerated amphiphilic protein layer according to an example embodiment of the disclosure.

FIG. 3. Silk-FET architecture and fabrication. a,b) Graphic representation of an IGZO silk-FET with lateral gate electrode interfaced with an ultrathin silk layer (a), with a microscope image of the device (b). c) Fabrication schematics. d,e) Microscope photographs of the ultrathin silk films patterned in squares (d) and stripes (e) on a Si/SiO₂ substrate (scale bars: 50 μm). f,g) Atomic force micrographs of stripe-patterned silk films (f, scale bar: 10 μm), and profile (g, inset).

FIG. 4. Silk-FET operating mechanism. a) Representation of a planar capacitor with electrodes in direct contact with an ultrathin silk layer in either dry or humid conditions—left and right, respectively—displaying the expected lateral profiles of the potential (black) and of the electric field (red) across the insulating layer in the two cases. b) Transfer characteristic curve of a silk-FET in either dry or humid conditions. c) Specific gate capacitance measurement performed in humid conditions.

FIG. 5. Breath sensing. a) Transfer characteristics of a silk-FET—with Au electrodes measured in proximity to the mouth, showing a reversible transition between the field-effect and the electrolyte gating modes. b) Time-dependent measurement of the breath sensing dynamics, which are characterized by a fast response time of ˜30 ms and a recovery of 300 ms. c) Continuous monitoring of multiple breath cycles in the course of approximately 20 s. d) Photograph of an array of breath sensors on a surgical mask (scale bar: 0.5 mm).

FIG. 6. Atomic force microscope images and thickness profile of ultrathin silk films on a Si/SiO₂ substrate, at different processing stages: a) Pristine silk (film edge obtained by scratching the film with a sharp tip); b) silk film after water rinsing; c) silk film after PMMA deposition, patterning and acetone bath.

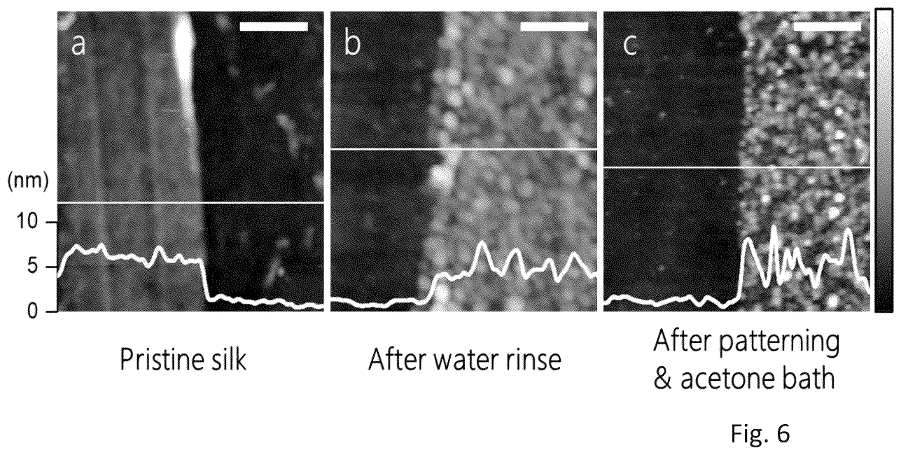

FIG. 7. Silk film thickness values as a function of spin-coating speed and initial concentration of the silk solution. Shaded area corresponds to thickness ranges used in this work.

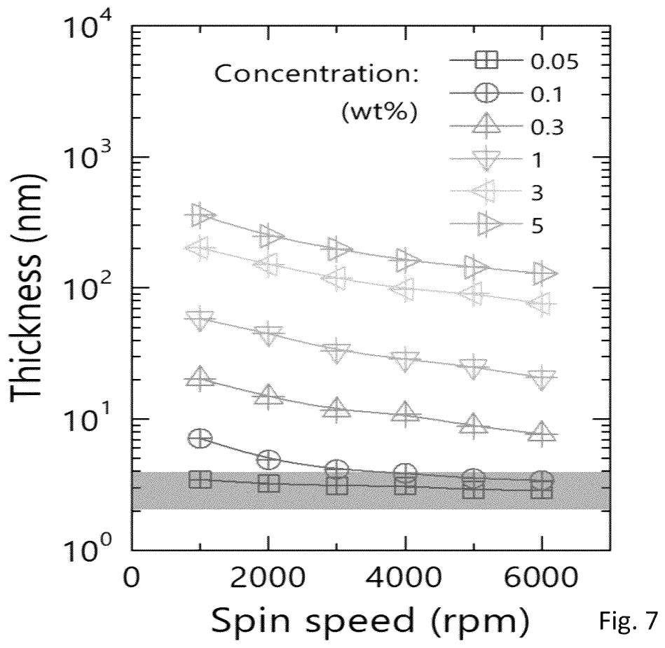

FIG. 8. Electrical characterization of a conventional bottom-gated IGZO device on a Si/SiO₂ wafer (SiO₂ thickness ˜300 nm, 10.8 nF/cm²) with Au electrodes (channel width and length are 1000 and 50 μm, respectively). a, b) The transfer (a) and output curves (b) exhibit well-behaved n-type FET characteristics in the linear and saturation regimes with an electron mobility of 5.63 cm²/Vs, a threshold voltage V_{T}=10.8 V, and a subthreshold swing 2.13 V/decade. c) Transfer curves obtained with either silk or PMMA as capping layer, showing negligible differences.

FIG. 9. Contact resistance values for silk-FETs fabricated with Au and Al contact electrodes, measured in either bottom-gate or side-gate configurations. Au electrodes present a larger contact resistance with respect to the Al contacts, which is particularly evident in side-gate operation.

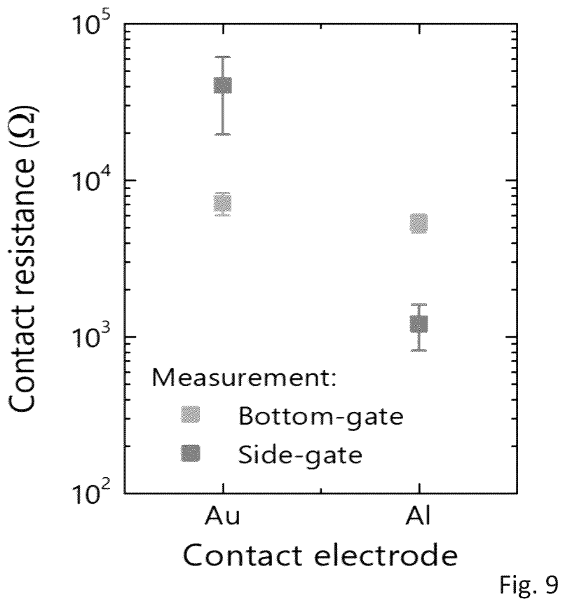

FIG. 10. Cycling stress test of the humidity sensing silk-FET, where the device is transitioned for 20 cycles between high and low humidity settings.

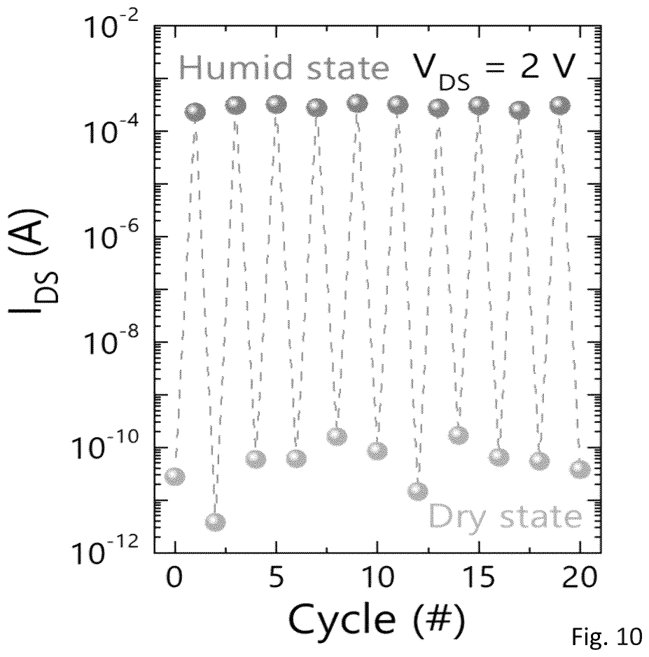

### DETAILED DESCRIPTION

Before the present disclosure is described in further detail, it is to be understood that the disclosure is not limited to the particular embodiments described. It is also understood that the terminology used herein is for the purpose of describing particular embodiments only, and is not intended to be limiting. The scope of the present disclosure will be limited only by the claims. As used herein, the singular forms “a”, “an”, and “the” include plural embodiments unless the context clearly dictates otherwise.

It should be apparent to those skilled in the art that many additional modifications beside those already described are possible without departing from the inventive concepts. In interpreting this disclosure, all terms should be interpreted in the broadest possible manner consistent with the context. Variations of the term “comprising” should be interpreted as referring to elements, components, or steps in a non-exclusive manner, so the referenced elements, components, or steps may be combined with other elements, components, or steps that are not expressly referenced.

Embodiments referenced as “comprising” certain elements are also contemplated as “consisting essentially of” and “consisting of” those elements. When two or more ranges for a particular value are recited, this disclosure contemplates all combinations of the upper and lower bounds of those ranges that are not explicitly recited. For example, recitation of a value of between 1 and 10 or between 2 and 9 also contemplates a value of between 1 and 9 or between 2 and 10.

As used herein, “silk fibroin” refers to silk fibroin protein whether produced by silkworm, spider, or other insect, or otherwise generated (Lucas et al., Adv. Protein Chem., 13:107-242 (1958)). Any type of silk fibroin can be used in different embodiments described herein. Silk fibroin produced by silkworms, such as Bombyx mori, is the most common and represents an earth-friendly, renewable resource. For instance, silk fibroin used in a silk film may be attained by extracting sericin from the cocoons of B. mori. Organic silkworm cocoons are also commercially available. There are many different silks, however, including spider silk (e.g., obtained from Nephila clavipes), transgenic silks, genetically engineered silks, such as silks from bacteria, yeast, mammalian cells, transgenic animals, or transgenic plants, and variants thereof, that can be used. See, e.g., WO 97/08315 and U.S. Pat. No. 5,245,012, each of which is incorporated herein by reference in their entireties.

Silk has emerged as a uniquely versatile biomaterial platform, able to target a wide array of applications across several disciplines in the life and materials sciences. Indeed, besides its well-known use in luxury fabrics, current research efforts leverage the exclusive and multifaceted properties of silk fibroin—the structural protein of silk fibers—and its versatile processability to achieve multifunctional and multiscale platforms with arbitrary shapes and form factors. Some examples of such platforms include biomedical implants and cell scaffolds, biochemical sensing interfaces, bioresponsive coatings, sustainable design products, as well as transient optics, photonics, and electronics. In particular, the latter set of technological applications have greatly profited from the possibility to precisely pattern silk through various techniques including casting, nanoimprinting, inkjet printing, as well as with both traditional and advanced photolithography methods—such as UV, multiphoton, e-beam, and hard-mask lithography. These remarkable developments have achieved excellent lateral resolutions at the wafer scale. In recent years, increased control over naturally-derived structural protein formulations and their self-assembly has enabled the application of high-resolution manufacturing techniques of silk-based materials, leading to bioactive interfaces with unprecedented miniaturized formats and functionalities.

Disclosed herein are functionalities that arise from tuning the biomaterial thickness at the nanoscale in the context of solid-state electronics. In particular, at the length scales disclosed herein, the absorption and transport of water molecules in the biomaterial—which can be introduced from either direct vapor streams or from changes in environmental humidity—lead to the dynamic and reversible formation of Electrical Double-Layers (EDLs) at the semiconductor/silk and at the metal/silk interfaces, which is exploited in inorganic thin-film Field-Effect Transistors (silk-FETs) that can readily switch from traditional field-effect mode to electrolyte-gated operation. This humidity-controlled reconfigurability is showcased within a compact and highly sensitive breath sensor.

Disclosed herein is a hybrid biopolymer-semiconductor device obtained by integrating nanoscale silk layers in a well-established class of inorganic field-effect transistors (silk-FETs). The devices offer two distinct modes of operation—either traditional field-effect or electrolyte-gated—enabled by the precisely controlled thickness, morphology, and biochemistry of the integrated silk layers. The different operational modes are selectively accessed by dynamically modulating the free-water content within the nanoscale protein layer from the vapor phase. The utility of these hybrid devices is illustrated in a highly sensitive and ultrafast breath sensor, highlighting the opportunities offered by the integration of nanoscale biomaterial interfaces in conjunction with traditional semiconductor devices, enabling functional outcomes at the intersection between the worlds of microelectronics and biology.

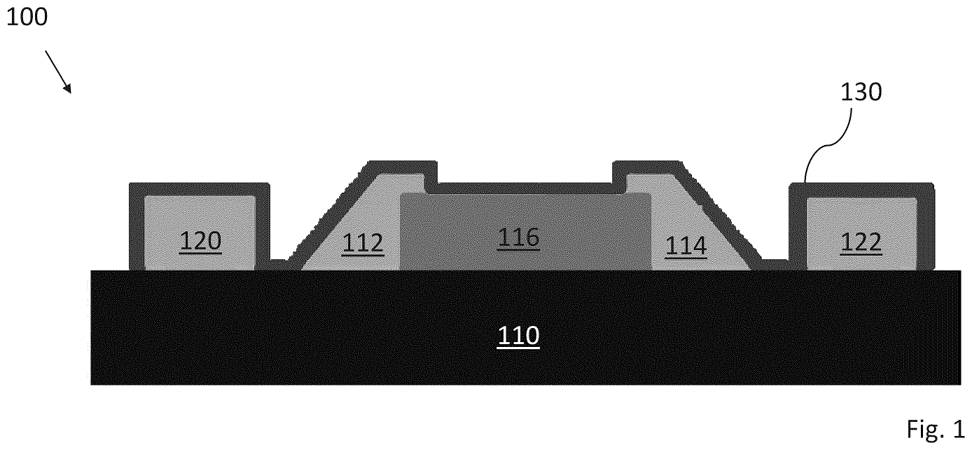

With reference to FIG. 1, a device 100 according to an example embodiment may include a first layer 116. This first layer 116 may be conductive or semiconductive. In the example of FIG. 1, the first layer 116 is semiconductive and formed of a semiconducting material. In example embodiments, the first layer 116 that is semiconductive may be part of a transistor and may be described as a semiconductor layer 116 herein.

Additionally, the device 100 may include a second layer 120/122, which may be conductive or semiconductive. In the example of FIG. 1, the second layer 120/122 is conductive. Furthermore, the second layer 120/122 may be a lateral gate electrode of the transistor and may be referred to herein as lateral gate electrode 120/122. In the example embodiment illustrated in FIG. 1, the lateral gate electrode and the semiconductor layer may not overlap in a cross-section view. Furthermore, in example embodiments, the transistor may include source electrode 112 and gate electrode 114, which may both be conductive.

A regenerated amphiphilic protein layer 130 may be on the first layer and/or the second layer. In example embodiments, “on” may mean in contact with rather than denoting a specific sequence or ordering. In example embodiments, the regenerated amphiphilic protein layer 130 may be formed of a biomaterial such as silk fibroin. For example, the regenerated amphiphilic protein layer 130 may be a regenerated silk fibroin layer.

In an example embodiment, each of the first layer 116, the second layer 120/122, and the regenerated amphiphilic protein layer 130 may be formed on a substrate 110. The substrate 110 may be planar, and may be formed of any suitable material, including but not limited to plastic, Si/SiO₂, or bioinspired materials. In an example, the substrate 110 is Si/SiO₂.

The regenerated amphiphilic protein layer may be structured such that in a first hydration state of the regenerated amphiphilic protein layer, a first electrical double layer (EDL) may be formed at an interface between the first layer 116 and the regenerated amphiphilic protein layer 130, and a second EDL may be formed at an interface between the second layer 120/122 and the regenerated amphiphilic protein layer 130.

In example embodiments, the first and second EDLs, which may be formed in the first hydration state, may enhance current flow by over six orders of magnitude.

In example embodiments, the first EDL may include electronic surface charges and oppositely charged ions aligned at the interface between the first layer and the regenerated amphiphilic protein layer, and the second EDL may include electronic surface charges and oppositely charged ions aligned at the interface between the second layer and the regenerated amphiphilic protein layer.

While example embodiments are described with reference to FIG. 1, which illustrates an example ordering of elements of device 100 including the first layer 116, the second layer 120/122, and the regenerated amphiphilic protein layer 130, such ordering is solely for purposes of illustration and embodiments are not limited thereto. Furthermore, while materials forming the elements as described herein may be deposited in a certain sequence—e.g., as illustrated, the first layer 116 and second layer 120/122 may be formed on the substrate 110, and the regenerated amphiphilic protein layer 130 may be formed on the first layer 116 and second layer 120/122, embodiments are not limited thereto.

In an example embodiment, the regenerated amphiphilic protein layer 130 may be accessible to environmental moisture. The regenerated amphiphilic protein layer 130 may capture the environmental moisture to initiate the first hydration state of the regenerated amphiphilic protein layer 130, and may release the captured environmental moisture to initiate a second hydration state of the regenerated amphiphilic protein layer 130 as further described herein. In example embodiments, the first hydration state may correspond to a regenerated amphiphilic protein layer 130 that has captured H₂O molecules, and the second hydration state may correspond to an absence (e.g., a complete or partial absence) of captured H₂O molecules in the regenerated amphiphilic protein layer 130. In other words, the second hydration state may correspond to no hydration. However, embodiments are not limited thereto, and the first and second hydration states of the regenerated amphiphilic protein layer 130 may be initiated in the presence or absence of other electrolytes.

In the second hydration state of the regenerated amphiphilic protein layer, the first EDL and the second EDL may not be formed. Instead, for example, capacitive coupling between the lateral gate electrode 120/122 and the semiconductor layer 116 may be determined by a permittivity of the regenerated amphiphilic protein layer 130. In example embodiments, in the second hydration state, there may be insufficient capacitive coupling between the lateral gate electrode and the semiconductor layer for modulating a charge carrier density within the semiconductor layer.

In example embodiments, when the regenerated amphiphilic protein layer transitions from the second hydration state to the first hydration state, the transistor transitions from a field-effect operating mode to an electrolyte-gated operating mode. For example, the transistor transitions from the field-effect operation of a metal-insulator-semiconductor structure to that of an electrolyte-gated device.

In example embodiments, the regenerated amphiphilic protein layer 130 may be formed by depositing silk fibroin films each less than 5 nm through spin-coating a 0.01-0.1% wt or 0.05% wt silk solution to form a deposited silk film, rinsing the deposited silk film in a bath of deionized water, and patterning the deposited silk film.

It has been unexpectedly found that the regenerated amphiphilic protein layer 130 may be tuned at the nanoscale (e.g., at the time of manufacture) with this example method. Furthermore, it has unexpectedly been found that functionalities may arise from tuning the thickness of the regenerated amphiphilic protein layer 130 at the nanoscale. In example embodiments, the regenerated amphiphilic protein layer may have a thickness of between 1 nm and 20 nm, between 2 nm and 15 nm, or between 3 nm and 10 nm, including but not limited to, a thickness of at least 1 nm, at least 2 nm, at least 3 nm, at least 4 nm, or at least 5 nm, and a thickness of at most 20 nm, at most 15 nm, at most 10 nm, or at most 5 nm. Tuning of the thickness to these ranges may unexpectedly and advantageously provide for controlled/controllable absorption and release of water or other chemical species in the gaseous or liquid phase.

In an example embodiment, patterning the deposited silk film includes O₂ plasma etching the deposited silk film through a photoresist mask using poly(methyl methacrylate) (PMMA) as a passivation layer.

In example embodiments, the semiconducting material of the semiconductor layer 116 may include any semiconducting material, such as but not limited to polymer, small molecule, carbon-based (e.g., graphene or nanotubes) semiconductors, etc. In an example, the semiconducting material is indium gallium zinc oxide (IGZO).

In example embodiments, the device 100 may include a bottom gate electrode (not shown in FIG. 1) between the substrate 110 and the semiconductor layer 116 for operating the transistor in the field-effect mode.

With reference to FIG. 1, example embodiments may include a semiconductor device 100 comprising a substrate 110, a source electrode 112, a drain electrode 114, a lateral gate electrode 120/122, and a semiconductor layer 116, each on the substrate 110. The semiconductor device 100 may further include a regenerated amphiphilic protein layer 130 on the semiconductor layer and the gate electrode. The regenerated amphiphilic protein layer 130 may also be on the source electrode 112 and the drain electrode 114. The regenerated amphiphilic protein layer 130 may be structured to be exposed to humidity to capture H₂O molecules and thereby transition from a field-effect mode to an electrolyte-gated mode.

In example embodiments, the humidity may be from breath exhalation, and the regenerated amphiphilic protein layer 130 may be structured to be in the electrolyte-gated mode during the breath exhalation.

In the electrolyte-gated mode, a first electric double layer (EDL) may be formed at an interface between the lateral gate electrode 120/122 and the regenerated amphiphilic protein layer, and a second electric double layer (EDL) may be formed at an interface between the regenerated amphiphilic protein layer 130 and the semiconductor layer 116.

In example embodiments, the regenerated amphiphilic protein layer 130 may be further structured for the captured H₂O molecules to be extracted during breath inhalation to thereby transition from the electrolyte-gated mode to the field-effect mode.

In example embodiments, the regenerated amphiphilic protein layer 130 may be structured to be in the electrolyte-gated mode during the breath exhalation and in the field-effect mode during the breath inhalation.

In one example, the breath exhalation may cause the regenerated amphiphilic protein layer 130 to transition from the field-effect mode to the electrolyte-gated mode in about 30 milliseconds, and the breath inhalation may cause the regenerated amphiphilic protein layer 130 to transition from the electrolyte-gated mode to the field-effect mode in about 300 milliseconds.

In example embodiments, the transitions between the electrolyte-gated mode and the field-effect mode enable tracking of multiple breath cycles.

In example embodiments, the semiconductor device 100 may include a bottom gate electrode (not shown) between the substrate 110 and the semiconductor layer 116.

In example embodiments, the regenerated amphiphilic protein layer may be a regenerated silk fibroin layer. The regenerated amphiphilic protein layer may have thickness of between 1 nm and 20 nm, between 2 nm and 15 nm, or between 3 nm and 10 nm, including but not limited to, a thickness of at least 1 nm, at least 2 nm, at least 3 nm, at least 4 nm, or at least 5 nm, and a thickness of at most 20 nm, at most 15 nm, at most 10 nm, or at most 5 nm.

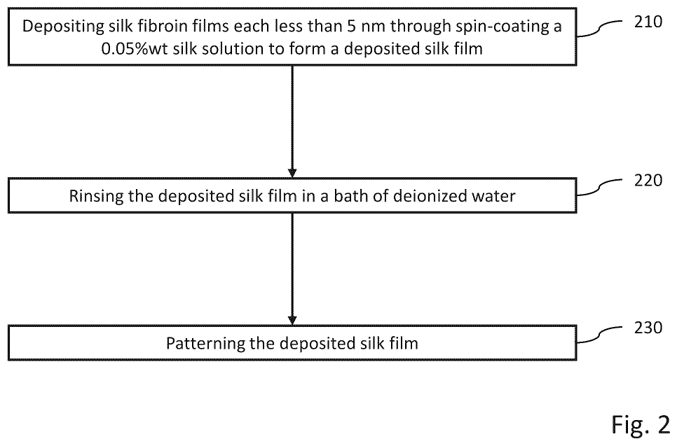

With reference to FIG. 2, a method of forming a regenerated amphiphilic protein layer according to example embodiments may include depositing (210) silk fibroin films each less than 5 nm through spin-coating a 0.01-0.1% wt or 0.05% wt silk solution to form a deposited silk film, rinsing (220) the deposited silk film in a bath of deionized water; and patterning (230) the deposited silk film.

In example embodiments, the patterning the deposited silk film may include O₂ plasma etching the deposited silk film through a photoresist mask using poly(methyl methacrylate) (PMMA) as a passivation layer.

In example embodiments, the generated amphiphilic protein layer may be formed on a first layer and a second layer. The first layer may be conductive or semiconductive and the second layer may be conductive or semiconductive.

In example embodiments, the regenerated amphiphilic protein layer may be structured such that in a hydrated state, a first electrical double layer (EDL) is formed at an interface between the first layer and the regenerated amphiphilic protein layer and a second EDL is formed at an interface between the second layer and the regenerated amphiphilic protein layer.

Unless otherwise specified or indicated by context, the terms “a”, “an”, and “the” mean “one or more.” For example, “a molecule” should be interpreted to mean “one or more molecules.” As used herein, “about”, “approximately,” “substantially,” and “significantly” will be understood by persons of ordinary skill in the art and will vary to some extent on the context in which they are used. If there are uses of the term which are not clear to persons of ordinary skill in the art given the context in which it is used, “about” and “approximately” will mean plus or minus ≤10% of the particular term and “substantially” and “significantly” will mean plus or minus >10% of the particular term.

As used herein, the terms “include” and “including” have the same meaning as the terms “comprise” and “comprising.” The terms “comprise” and “comprising” should be interpreted as being “open” transitional terms that permit the inclusion of additional components further to those components recited in the claims. The terms “consist” and “consisting of” should be interpreted as being “closed” transitional terms that do not permit the inclusion of additional components other than the components recited in the claims. The term “consisting essentially of” should be interpreted to be partially closed and allowing the inclusion only of additional components that do not fundamentally alter the nature of the claimed subject matter.

All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

All references, including publications, patent applications, and patents, cited herein are hereby incorporated by reference to the same extent as if each reference were individually and specifically indicated to be incorporated by reference and were set forth in its entirety herein.

Preferred aspects of this invention are described herein, including the best mode known to the inventors for carrying out the invention. Variations of those preferred aspects may become apparent to those of ordinary skill in the art upon reading the foregoing description. The inventors expect a person having ordinary skill in the art to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

While the invention has been illustrated and described in detail in the foregoing drawings and description, the same is to be considered as illustrative and not restrictive in character, it being understood that only illustrative embodiments thereof have been shown and described and that all changes and modifications that come within the spirit of the invention are desired to be protected.

For example, any of the features or functions of any of the embodiments disclosed herein may be incorporated into any of the other embodiments disclosed herein.

While the disclosure has been disclosed in connection with certain embodiments shown and described in detail, various modifications and improvements thereon will become readily apparent to those skilled in the art. Accordingly, the spirit and scope of the present disclosure is not to be limited by the foregoing examples but is to be understood in the broadest sense allowable by law.

### EXAMPLES

### Nanometric Biomaterial Interfaces on Thin-Film Transistors

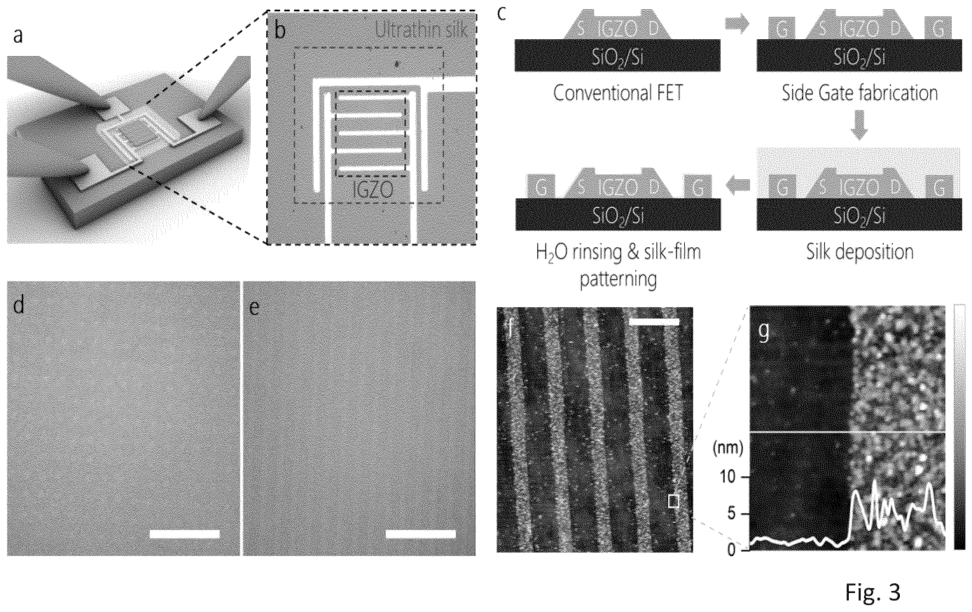

In the past two decades, Indium Gallium Zinc Oxide (IGZO) has attracted considerable attention as a high mobility, easily processable transparent oxide semiconductor, finding application in backplane microelectronics for large-area and flexible display technologies. The hybrid bio-device structure disclosed in this work, displayed in FIG. 3a, is based on this semiconductor technology, where an IGZO transistor is fabricated on a Si/SiO₂ substrate, along with a coplanar side-gate electrode used for operating the silk-FET in electrolyte-gated mode. The deposition of ultrathin fibroin films (<5 nm) was performed by spin-coating a low-concentration silk solution (0.05% wt) directly on the device, followed by a rinsing bath in deionized water. The film was then patterned by O₂ plasma etching the undesired areas through a photoresist mask, using poly(methyl methacrylate) (PMMA) as passivation layer to preserve the fibroin from the harsh chemicals used in conventional photolithography processes, subsequently removed via an acetone bath. Due to the strong adhesive properties of the silk fibroin, which, without wishing to be bound by any particular theory, may be ascribable to its amphiphilic molecular structure and its dense network of hydrogen bonds, these fabrication steps result in stable and highly transparent biomaterial layers with controlled thicknesses comprised between 3 and 300 nm (see FIG. 3f, g, 6 and 7), exhibiting lateral resolutions of few μm.

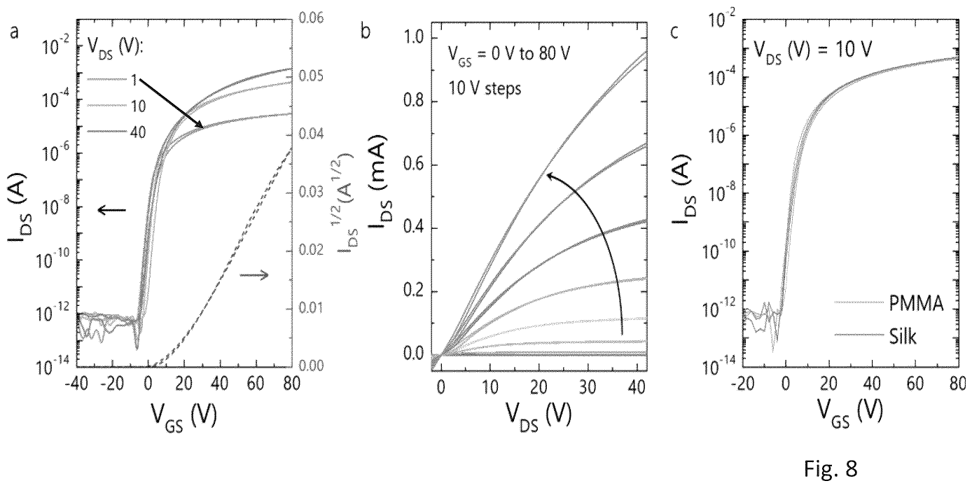

In normal humidity and temperature conditions—referred as “dry conditions” herein—the presence of the silk on the top interface of the IGZO does not influence the characteristic behavior of the device. FIG. 8 reports the transfer and output characteristics of an IGZO transistor measured in bottom-gate configuration when exposed to either PMMA or silk. In spite of the different materials properties at these interfaces, the latter set of measurements shows negligible variations in either threshold voltage (V_{T}), subthreshold swing, hysteresis, OFF drain-source current or charge mobility in the silk-FET, as long as the device is maintained in dry conditions. In agreement with previous examples of field-effect transistors based on silk dielectrics, these results confirm that the polar moieties of the fibroin—in absence of water—do not introduce significant trapping sites or energetic disorder within the IGZO that could result in a degradation of the transistor performances.

### Dual-Mode of Operation in Silk-FETs

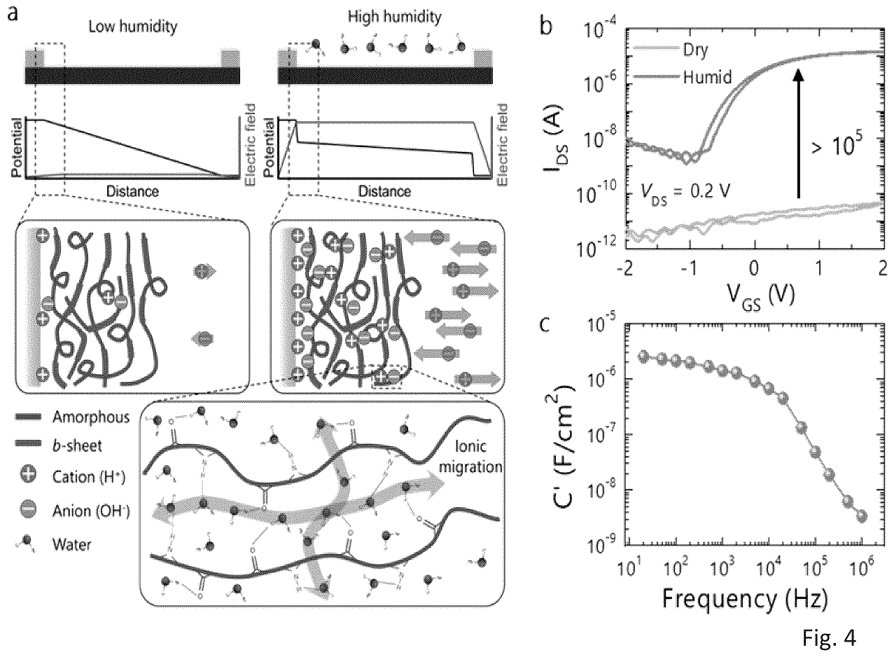

FIG. 4a shows the proposed mode of operation of silk-FETs when controlled through the lateral gate electrode in either dry or humid environmental conditions. In conventional FETs, the application of a gate potential modulates the population of charge carriers in the transistor channel through a capacitive effect, which is determined by the dielectric polarizability of the gate insulator as well as by the overall geometry of the device—i.e., by the overlap area between the gate electrode and the semiconductor channel, and their relative distance. In conventional FETs structures, where the gate electrode typically lies over (or under) the transistor channel area, the specific capacitances established through this mechanism are generally in the range of 0.01-1 μFcm⁻². In spite of the good dielectric properties of silk, when our devices operate in dry conditions the absence of a geometric overlap between the lateral gate electrode and the silk-FET channel results in a negligible capacitive coupling, insufficient for modulating the charge carrier density within the IGZO. Conversely, in high-humidity conditions, the gating mechanism of silk-FETs radically changes thanks to the formation of two EDLs at the semiconductor/silk and at the gate metal/silk interfaces respectively.

To a first approximation, EDLs can be envisioned as conventional parallel plate capacitors where electronic surface charges and oppositely charged ions are aligned at the (semi)conductor/electrolyte interfaces in dense and closely localized distributions. In electrolyte-gated FETs, these strong capacitive couplings—generally well exceeding 10 μFcm⁻²—lead to extensive charge modulations in the transistor channel with sub-volt polarizations and only a minor dependence on the dielectric film thickness or on the electrode geometry. In the disclosed devices, the EDL formation is linked to the ability of silk materials to capture H₂O molecules from the environmental moisture, which, without wishing to be bound by any particular theory, may be ascribed to the unique thin-film microstructure that emerges from the device processing steps, which include an acetone bath (see Experimental Section). Indeed, water absorption and transport in silk have been the objects of several studies, which have consistently highlighted the primary influence of the fibroin secondary structure on both these properties. The relative ratio of amorphous and crystalline regions in the films may affect, among other properties, their hydration dynamics. For example, while increased crystalline content is known to induce a water vapor barrier effect, silk films that are immersed in polar organic solvents—such as methanol, ethanol or acetone—exhibit a secondary structure arrangement that is characterized by a greater capacity to absorb water. Moreover, larger degrees of free water uptake in the films, which have been shown to reach up to 12% wt in high humidity settings, may be associated with an enhanced plasticization of the silk chains, which can play a role in favoring fast water transport.

The marked difference in device behavior between dry and the high humidity conditions can be appreciated in FIG. 4b, which clearly displays the transition of the side-gate silk-FET from a conventional field-effect mechanism—based on dielectric polarization and hence showing extremely low OFF currents and virtually no modulation—to the electrolyte-gated mode of operation. In humid conditions, the device indeed exhibits well-behaved n-type device characteristics with an ON/OFF current ratio of about 10⁴, a threshold voltage of −0.27 V and a subthreshold swing of 0.18 V/decade.

The dramatic current enhancement achieved via EDL formation at the ultrathin silk interfaces exceeds 6 orders of magnitude (from tens to pA up to tens of μA), as visible from gate impedance measurements performed on the silk-FETs, from which was extracted specific capacitance C′ of few μFcm⁻² in humid conditions (FIG. 4c, capacitance values in dry conditions too low to be measured).

### Fast and High Sensitivity Breath Sensors

The ability to change the device operation mechanism upon exposure to humidity opens to new opportunities for bioelectronic sensing, especially in the context of respiratory monitoring and breath analysis. In recent years, several pathologic conditions and respiratory syndromes have been correlated to abnormalities in breathing frequency and depth, such as cardiovascular and pulmonary diseases, as well as sleep apnea. For this reason, increasing efforts have been dedicated to the development of compact and cost-effective monitoring devices for breath diagnostics, with a particular attention towards achieving high sensitivities and sub-second responses in order to closely follow the breathing cycle dynamics. Among respiratory monitoring technologies, a common sensing strategy relies on moisture absorption and desorption by a water responsive electronic material, which is of particular technological relevance when it can be directly embedded into conventional electronics.

Thanks to their nanometric thickness and good water transport properties, the humidity-driven reconfigurability of the disclosed silk-FETs from the field-effect to the electrolyte-gated mode of operation is characterized by marked reversibility and fast dynamics. These devices can indeed be exploited towards breath sensing applications, achieving sensitivities and response times that are comparable to or exceed prior examples.

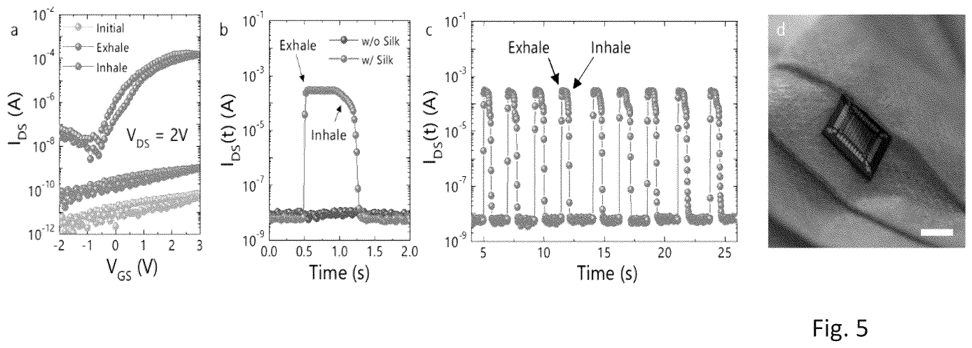

FIG. 5a shows the three consecutively measured transfer curves of a silk-FET, acquired in different moments during one breathing cycle, composed by an exhalation phase followed by inhalation. In light of the mechanism described herein, the initially dry silk-FET is biased and then exposed to the breath humidity during exhalation, and thus transitions from a non-modulating field-effect mode to electrolyte-gating. Subsequently, upon inhalation, the water molecules are extracted from the nanoscale silk layer, almost completely restoring the initial dry conditions. With a response time of ˜30 ms and a recovery of 300 ms, the fast transition dynamics allow the precise tracking of multiple breath cycles, maintaining high sensitivity with a 10⁴ increase in I_{DS} signal upon exhalation (see FIG. 3b,c).

### Conclusion

In conclusion, this disclosure provides a new perspective on the potential of biohybrid electronic nanointerfaces based on silk. The seamless integration of inorganic semiconductor technologies with nanoscale biopolymer thin-films generates radical device concepts and configurations, where the exceptional performances of conventional microelectronic components merge with the unique functionalities granted by biopolymers. Indeed, by carefully controlling the processing conditions from the solution-phase, the nanoscale engineering of the silk film thickness allows the optimization of the water transport properties and of the surface interactions of this multifaceted biomaterial, thus enabling unprecedented reconfigurability in microelectronic platforms. In the context of bioelectronics and breath sensing, the already excellent sensitivity and fast dynamics of the silk-FETs could be complemented by biochemical sensing functionalities, which could be implemented for example by introducing bioreactive elements within the silk matrix, towards multianalyte and environmentally stable microelectronic sensing platforms.

### Experimental Section

### Chemicals

Indium nitrate hydrate (In(NO₃)₃·xH₂O, 99.999%, Aldrich), gallium nitrate hydrate (Ga(NO₃)₃·xH₂O, 99.999%, Aldrich), zinc nitrate hexahydrate (Zn·6H₂O, 99.999%, Aldrich), Deionized water was obtained from a milliQ Nanopure System and exhibited a resistivity of ca. 18 Ω·cm.

### Metal Hydrate Precursor Solution Preparation and Processing

Solution for IGZO was prepared by the following procedure. Metal precursors comprising powders of indium nitrate hydrate, gallium nitrate hydrate, and zinc nitrate hexahydrate were dissolved in distilled water. The resulting solution was then thoroughly stirred for more than 12 h, and filtered through a 0.22 μm membrane filter before use.

### Silk Preparation

Silk fibroin was extracted from the cocoons of the Bombyx mori silkworm with established protocols (See D. N. Rockwood, R. C. Preda, T. Yücel, X. Wang, M. L. Lovett, D. L. Kaplan, Nat. Protoc. 2011, 6, 1612.). Briefly, cocoons were cut in small pieces and boiled for 10 min in a 0.02 m Na₂CO₃ water solution to remove the hydrophilic sericin protein. The extracted silk fibers were rinsed with distilled water and then dried under ambient air for 2 days. The dried silk fibers were dissolved in a 9.3 m LiBr solution at 60° C. for 4 h, stirring after 1 and 2 h had elapsed. The dissolved silk fibroin was dialyzed against distilled water in dialysis cassettes (Slide-a-Lyzer, Pierce, MWCO 3.5K) for 36 hours to obtain a 5-8 % wt silk fibroin solution in water, followed by centrifuging twice at 8000 rpm. The clear supernatant was collected and then further diluted in deionized water to 0.05% wt, unless otherwise noted, and stored at 4° C. for further processing.

### FET Fabrication

Si wafers (heavily n-doped, p<0.005 Ω·cm, universitywafer) with 300 nm thick SiO₂ dielectric were used as the bottom gate and substrate for FET fabrication. The substrates, 1 cm×1 cm in size, were immersed in piranha (conc. H₂SO₄ and 30% aqueous H₂O₂, 3:1 by volume) until the oxygen stopped bubbling. Once the substrates cooled down, they were rinsed with water multiple times. Aqueous precursor solution of inorganic materials was deposited via spin-coating onto the freshly cleaned substrates. The dried films were then annealed 350° C. for 30 min to decompose the ligand. The thickness of the active layer was around 5-6 nm. The IGZO film was then patterned via conventional photolithography and wet etching by HCl:H₂O (1:100) for 1 min. A 50-nm-thick Al or Au source, drain and gate electrodes were deposited by thermal evaporation onto photolithographically patterned mask.

### Ultrathin Silk Deposition and Patterning

The diluted silk solution was spin-cast on the IGZO FETs at 3000 rpm, and subsequently rinsed in a deionized water bath, yielding a nanoscale thin film. Prior to photolithography, a protective PMMA (polymethyl methacrylate) C4 coating was spin-coated on the substrate (3000 rpm, baked at 180° C. for 1 min). Photoresist S1805 was spin-coated (3000 rpm, baked at 115° C. for 1 min), exposed through a photomask for 3 s, and developed for 1 min in MF-CD 26. O₂ etching was performed for 2 min at 100 W to remove the PMMA and the silk in the unexposed areas, and later followed by an acetone bath to remove the remaining photoresist and PMMA. Passivation of the electrodes was through deposition and photolithographic patterning of a SU8 layer.

### Measurements

Electrical measurements were performed with a parameter analyzer (Keithley 4200A-SCS) equipped with a capacitance-voltage unit. We grounded the source electrode and controlled the source-gate voltage, V_{GS}, and the source-drain voltage, V_{DS}. Experiments in dry and humid conditions were performed using a custom chamber. Thin-film morphologies were acquired by atomic force microscopy (Bruker, Innova SPM).

1. A device, comprising:
a first layer, wherein the first layer is conductive or semiconductive; and
a regenerated amphiphilic protein layer on the first layer, the regenerated amphiphilic protein layer structured such that:
in a first hydration state of the regenerated amphiphilic protein layer, a first electrical double layer (EDL) is formed at an interface between the first layer and the regenerated amphiphilic protein layer.

2. The device of claim 1, further comprising:
a second layer, wherein:
the second layer is conductive or semiconductive;
the regenerated amphiphilic protein layer is on the second layer; and
in the first hydration state of the regenerated amphiphilic protein layer, a second EDL is formed at an interface between the second layer and the regenerated amphiphilic protein layer.

3. The device of claim 1, wherein the regenerated amphiphilic protein layer is accessible to environmental moisture.

4. The device of claim 3, wherein the first hydration state is initiated by capture of the environmental moisture by the regenerated amphiphilic protein layer.

5. The device of claim 3, wherein the regenerated amphiphilic protein layer is formed by:
depositing silk fibroin films each less than 5 nm through spin-coating a 0.01-0.1% wt or 0.05% wt silk solution to form a deposited silk film;
rinsing the deposited silk film in a bath of deionized water; and
patterning the deposited silk film.

6. The device of claim 5, wherein the patterning the deposited silk film includes O₂ plasma etching the deposited silk film through a photoresist mask using poly(methyl methacrylate) (PMMA) as a passivation layer.

7. The device of claim 2, wherein the first and second EDLs formed in the first hydration state enhance current flow by over six orders of magnitude.

8. The device of claim 2, wherein:
the first EDL includes electronic surface charges and oppositely charged ions aligned at the interface between the first layer and the regenerated amphiphilic protein layer; and
the second EDL includes electronic surface charges and oppositely charged ions aligned at the interface between the second layer and the regenerated amphiphilic protein layer.

9. The device of claim 2, wherein the first layer is a lateral gate electrode of a transistor, and the second layer is a semiconductor layer of the transistor.

10. The device of claim 9, wherein the lateral gate electrode and the semiconductor layer do not overlap in a cross-section view.

11. The device of claim 9, wherein the semiconductor layer is formed of a semiconducting material.

12. The device of claim 11, wherein the semiconducting material includes indium gallium zinc oxide (IGZO).

13. The device of claim 9, wherein in a second hydration state of the regenerated amphiphilic protein layer, the first EDL and the second EDL are not formed.

14. The device of claim 13, wherein the second hydration state corresponds to an absence of captured H₂O molecules in the regenerated amphiphilic protein layer.

15. The device of claim 14, wherein in the second hydration state, capacitive coupling between the lateral gate electrode and the semiconductor layer is determined by a permittivity of the regenerated amphiphilic protein layer.

16. The device of claim 15, wherein capacitive coupling is insufficient for modulating a charge carrier density within the semiconductor layer.

17. The device of claim 13, wherein when the regenerated amphiphilic protein layer transitions from the second hydration state to the first hydration state, the transistor transitions from a field-effect operating mode to an electrolyte-gated operating mode.

18. The device of claim 9, further comprising:
a substrate,
wherein the first layer and the second layer are each on the substrate.

19. The device of claim 18, further comprising:
a bottom gate electrode between the substrate and the semiconductor layer.

20. The device of claim 18, wherein the substrate is Si/SiO_{2.}

21. The device of claim 1, wherein the regenerated amphiphilic protein layer is a regenerated silk fibroin layer.

22. The device of claim 1, wherein the regenerated amphiphilic protein layer has a thickness of between 1 nm and 20 nm, between 2 nm and 15 nm, or between 3 nm and 10 nm, including but not limited to, a thickness of at least 1 nm, at least 2 nm, at least 3 nm, at least 4 nm, or at least 5 nm, and a thickness of at most 20 nm, at most 15 nm, at most 10 nm, or at most 5 nm.

23. A semiconductor device, comprising:
a substrate;
a source electrode, a drain electrode, a lateral gate electrode, and a semiconductor layer, each on the substrate; and
a regenerated amphiphilic protein layer on the semiconductor layer and the lateral gate electrode,
wherein the regenerated amphiphilic protein layer is structured to be exposed to humidity to capture H₂O molecules and thereby transition from a field-effect mode to an electrolyte-gated mode.

24-33. (canceled)

34. A method of forming a regenerated amphiphilic protein layer, comprising:
depositing silk fibroin films each less than 5 nm through spin-coating a 0.01-0.1% wt or 0.05% wt silk solution to form a deposited silk film;
rinsing the deposited silk film in a bath of deionized water; and
patterning the deposited silk film.

35-37. (canceled)
